(19) United States
(12) Patent Application Publication
(10) Pub. No.: US 2010/0059809 A1
(43) Pub. Date: Mar. 11, 2010

(54) NON-VOLATILE MEMORY AND METHOD OF FABRICATING THE SAME

(75) Inventors: Chi-Pin Lu, Hsinchu (TW); Jung-Yu Hsieh, Hsinchu (TW); Hsing-Ju Lin, Hsinchu (TW)

Correspondence Address: J C PATENTS, 4 VENTURE, SUITE 250, IRVINE, CA, 92618, US

(73) Assignee: MACRONIX INTERNATIONAL CO., LTD., Hsinchu (TW)

(21) Appl. No.: 12/268,593

(22) Filed: Nov. 11, 2008

Related U.S. Application Data
(60) Provisional application No. 61/095,315, filed on Sep. 9, 2008.

(51) Int. Cl. H01L 29/792; H01L 21/336

(52) U.S. Cl. 257/324; 438/287; 257/E29.309; 257/E21.423

(57) ABSTRACT

A method of fabricating a non-volatile memory is provided. First, a bottom oxide layer is formed on a substrate. Thereafter, a silicon-rich nitride layer is formed on the bottom oxide layer by using NH₃ and SiH₂Cl₂ or SiH₄, wherein the thickness of the silicon-rich nitride layer is less than about 40 Å, and the gas flow ratio of NH₃ to SiH₂Cl₂ or SiH₄ is about 0.2-0.5. Afterwards, a top oxide layer is formed on the silicon-rich nitride layer. Further, a gate is formed on the top oxide layer. Two doped regions are then formed in the substrate beside the gate.

### CROSS-REFERENCE TO RELATED APPLICATION

This application claims the priority benefit of U.S. provisional application Ser. No. 61/095,315 filed on Sep. 9, 2008. The entirety of the above-mentioned provisional application is hereby incorporated by reference herein and made a part of this specification.

### BACKGROUND OF THE INVENTION

1. Field of Invention

The present invention relates to a semiconductor device and a method of fabricating the same, and more generally to a non-volatile memory and a method of fabricating the same.

2. Description of Related Art

A non-volatile memory provides the property of multiple entries, retrievals and erasures of data, and is able to retain the stored information even when the electrical power is off. As a result, a non-volatile memory is widely used in personal computers and consumer electronic products.

A conventional non-volatile memory includes an oxide-nitride-oxide (ONO) composite layer and a gate sequentially disposed on a substrate, and source and drain regions disposed in the substrate beside the gate. As the degree of integration of the non-volatile memory is getting higher, the dimension and thickness of each layer of the same is reduced accordingly. However, the trapping capability of the non-volatile memory is degraded when the thickness of the silicon nitride layer is reduced to a certain value. For example, the non-volatile memory having a silicon nitride layer of more than 70 Å thick is demonstrated to be fully-capturing, but the trapping capability of the non-volatile memory having a silicon nitride layer of less than 40 Å thick is relatively poor.

Accordingly, it has become one of the main topics in the industry to fabricate a non-volatile memory having an ultra-thin nitride layer with good trapping capability.

### SUMMARY OF THE INVENTION

The present invention provides a non-volatile memory of which the trapping capability is enhanced when the ultra-thin silicon-rich nitride layer replaces the ultra-thin stoichiometric silicon nitride layer.

The present invention further provides a method of fabricating a non-volatile memory. The non-volatile memory fabricated based on the method of the present invention can provide an ultra-thin silicon-rich nitride layer with good trapping capability.

The present invention provides a method of fabricating a non-volatile memory. First, a bottom oxide layer is formed on a substrate. Thereafter, a silicon-rich nitride layer is formed over the bottom oxide layer by using NH₃ and SiH₂Cl₂ or SiH₄. Afterwards, a top oxide layer is formed on the silicon-rich nitride layer. Further, a gate is formed on the top oxide layer.

According to an embodiment of the present invention, the thickness of the silicon-rich nitride layer is less than about 40 Å, for example.

According to an embodiment of the present invention, the gas flow ratio of NH₃ to SiH₂Cl₂ or SiH₄ is about 0.2-0.5, for example.

According to an embodiment of the present invention, the silicon-rich nitride layer has a N/Si ratio of about 1.1-1.3, for example.

According to an embodiment of the present invention, the bottom oxide layer may be a silicon oxide layer.

According to an embodiment of the present invention, the top oxide layer may be a silicon oxide layer or a high dielectric constant (high-k) metal oxide layer.

According to an embodiment of the present invention, the step of forming the silicon-rich nitride layer includes performing a low pressure (LP) CVD process, a plasma enhanced (PE) CVD process, an electron cyclotron resonance (ECR) CVD process or an inductively coupled plasma (ICP) CVD process, for example.

According to an embodiment of the present invention, the temperature of the LPCVD process is about 600-650° C., for example.

According to an embodiment of the present invention, the method of forming the non-volatile memory further includes forming two doped regions in the substrate beside the gate after the step of forming the gate.

The present invention further provides a non-volatile memory including a substrate a bottom oxide layer, a silicon-rich nitride layer, a top oxide layer and a gate. The bottom oxide layer, the silicon-rich nitride layer, the top oxide layer and the gate are sequentially disposed on the substrate. It is noted that the thickness of the silicon-rich nitride layer is less than about 40 Å.

According to an embodiment of the present invention, the silicon-rich nitride layer has a N/Si ratio of about 1.1-1.3, for example.

According to an embodiment of the present invention, the bottom oxide layer may be a silicon oxide layer.

According to an embodiment of the present invention, the top oxide layer may be a silicon oxide layer or a high-k metal oxide layer.

According to an embodiment of the present invention, the non-volatile memory further includes two doped regions disposed in the substrate beside the gate.

In summary, the non-volatile memory fabricated based on the method of the present invention can provide an ultra-thin silicon-rich nitride layer with good trapping capability. Further, conventional ex-situ treatments such as a hydrogen treatment are not required to perform on the nitride layer to enhance the trapping capability, so that the cost is reduced and the competitiveness is improved.

In order to make the aforementioned and other objects, features and advantages of the present invention comprehensible, a preferred embodiment accompanied with figures is described in detail below.

### BRIEF DESCRIPTION OF THE DRAWINGS

FIGS. 1A to 1B are schematic cross-sectional views of a method of fabricating a non-volatile memory according to an embodiment of the present invention.

FIG. 2 illustrates a diagram of flat band voltage (V_{FB}) as a function of programming voltage (V_{PGM}) according to Samples 1 to 4 of the present invention.

### DESCRIPTION OF EMBODIMENTS

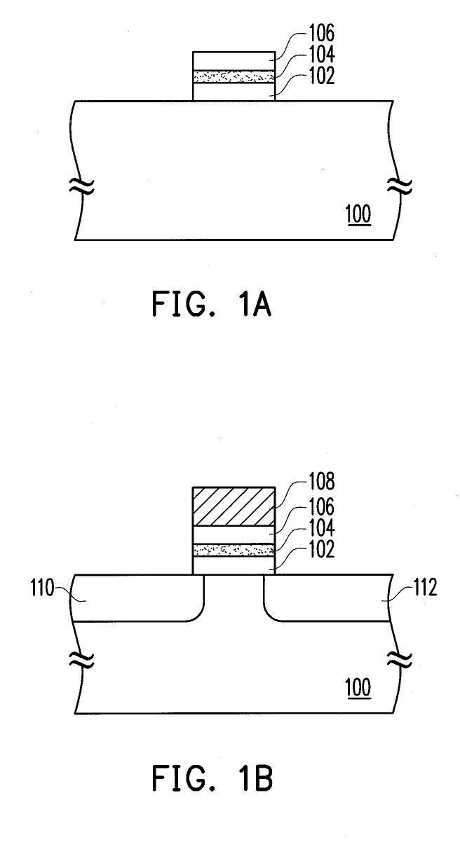

FIGS. 1A to 1B are schematic cross-sectional views of a method of fabricating a non-volatile memory according to an embodiment of the present invention.

Referring to FIG. 1A, a bottom oxide layer 102 is formed on a substrate 100. The substrate 100 may be a semiconductor substrate, such as a silicon substrate. The bottom oxide layer 102 may be a silicon oxide layer and the forming method thereof includes performing a thermal oxidation process or a chemical vapor deposition (CVD) process, for example.

Thereafter, a silicon-rich nitride layer 104 is formed over the bottom oxide layer 102 by using NH₃ and SiH₂Cl₂ or SiH₄. The gas flow ratio of NH₃ to SiH₂Cl₂ or SiH₄ has to be low enough to provide extra silicon atoms for forming the silicon-rich nitride layer. Preferably, the gas flow ratio of NH₃ to SiH₂Cl₂ or SiH₄ is about 0.2-0.5, for example. As a result, the silicon-rich nitride layer has a N/Si ratio of about 1.1-1.3, which is lower than the N/Si ratio of 1.34 of a stoichiometric silicon nitride (Si₃N₄) layer. In an embodiment, the silicon-rich nitride layer has a N/Si ratio of about 1.24, for example. The N/Si ratio is measured by X-ray photoelectron spectroscopy (XPS) analysis. Further, the thickness of the silicon-rich nitride layer 104 is less than about 40 Å. In an embodiment, the thickness of the silicon-rich nitride layer is about 35 Å, for example. The method of forming the silicon-rich nitride layer 104 includes performing a LPCVD process, a PECVD process, an ECRCVD process or an ICPCVD process, etc. In an embodiment, the silicon-rich nitride layer 104 is formed by performing a LPCVD process, and the temperature of the LPCVD process is about 600-650° C., for example.

Afterwards, a top oxide layer 106 is formed on the silicon-rich nitride layer 104. The top oxide layer 106 may be a silicon oxide layer or a high-k metal oxide layer for effective oxide thickness (EOT) reduction. The top oxide layer 106 may be formed through a surface oxidation process of the silicon-rich nitride layer 104 or through a CVD process.

Referring to FIG. 1B, a gate 108 is formed on the top oxide layer 106. The gate 106 may be a polysilicon layer, and the forming method thereof includes performing a CVD process, for example. Thereafter, two doped regions 110 and 112 are formed in the substrate 100 beside the gate 108. The method of forming the doped regions 110 and 112 includes performing an ion implantation process with N-type or P-type dopants. The non-volatile memory of the present invention is thus completed.

In the present invention, the non-volatile memory includes a substrate 100, a bottom oxide layer 102, a silicon-rich nitride layer 104, a top oxide layer 106, a gate 108 and two doped regions 110 and 112. The bottom oxide layer 102, the silicon-rich nitride layer 104, the top oxide layer 106 and the gate 108 are sequentially disposed on the substrate 100. The doped regions 110 and 112 are disposed in the substrate 100 beside the gate 108. It is noted that the thickness of the silicon-rich nitride layer 104 is less than about 40 Å.

Several Samples are provided in the following to prove the trapping capability of the non-volatile memory of the present invention. Samples 1 to 4 are non-volatile memories respectively having a stoichiometric silicon nitride layer of 90 Å thick, a silicon-rich nitride layer of 90 Å thick, a stoichiometric silicon nitride layer of 35 Å thick, and a silicon-rich nitride layer of 35 Å thick.

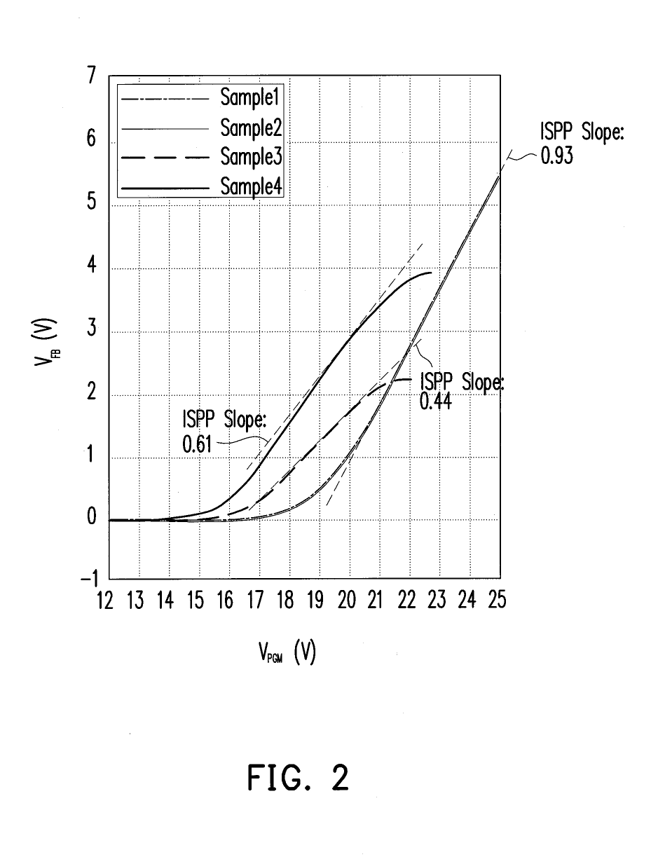

FIG. 2 illustrates a diagram of flat band voltage (V_{FB}) as a function of programming voltage (V_{PGM}) according to Samples 1 to 4 of the present invention. Incremental-step-pulse programming (ISPP) method is to apply a constant voltage step (Δ V_{PGM}) after successive Fowler-Nordheim (FN) programming. The ISPP slope indicates the trapping capability or capturing efficiency of the tested non-volatile memory. A nearly fully-capturing property gives an ISPP slope close to 1. On the other hand, a poor trapping capability or a lower capturing efficiency results in a lower ISPP slope.

As shown in FIG. 2, the curves of Sample 1 and Sample 2 are overlapped with each other, and the ISPP slope is about 0.93. That is, the trapping capability of the non-volatile memory having a stoichiometric silicon nitride layer of 90 Å thick (Sample 1) is similar to that of the non-volatile memory having a silicon-rich nitride layer of 90 Å thick (Sample 2), and Sample 1 and Sample 2 are demonstrated to be nearly fully-capturing. On the other hand, the ISPP slope of Sample 3 drops from 0.93 to 0.44 when the thickness of the stoichiometric silicon nitride layer of the non-volatile memory is reduced from 90 Å to 35 Å. However, the ISPP slope of Sample 4 is still up to 0.61 when the thickness of the silicon-rich nitride layer of the non-volatile memory is reduced from 90 Å to 35 Å.

In other words, the ISPP slope is close to 1 and indicates a nearly fully-capturing property when the non-volatile memory has a nitride layer of 90 Å thick. The material of the nitride layer is not important when a thick nitride layer is applied. On the other hand, the ISPP slope is deviated from 1 when the non-volatile memory has a nitride layer of 35 Å thick, and the trapping capability of the non-volatile memory having an ultra thin silicon-rich nitride layer (Sample 4) is better than that of the non-volatile memory having an ultra thin stoichiometric silicon nitride layer (Sample 3).

In summary, the non-volatile memory fabricated based on the method of the present invention can provide an ultra-thin silicon-rich nitride layer with good trapping capability. When the thickness of the nitride layer is reduced to less than 40 Å, replacing the stoichiometric silicon nitride layer with the silicon-rich nitride layer can solve the poor trapping capability issue. In the present invention, conventional ex-situ treatments such as a hydrogen treatment are not required to perform on the nitride layer to enhance the trapping capability, so that the cost is reduced and the competitiveness is improved.

Further, the ultra-thin silicon-rich nitride layer with good trapping capability is easily fabricated based the method of the present invention, so that the thickness and dimension of the ONO composite layer are reduced accordingly. Therefore, the whole dimension of the non-volatile memory is reduced, the required operation voltage of the same is lower, and the power consumption of the same is reduced as well.

This invention has been disclosed above in the preferred embodiments, but is not limited to those. It is known to persons skilled in the art that some modifications and innovations may be made without departing from the spirit and scope of this invention. Hence, the scope of this invention should be defined by the following claims.

What is claimed is:

1. A method of fabricating a non-volatile memory, comprising:
forming a bottom oxide layer on a substrate;
forming a silicon-rich nitride layer over the bottom oxide layer by using NH₃ and SiH₂Cl₂ or SiH₄;
forming a top oxide layer on the silicon-rich nitride layer; and
forming a gate on the top oxide layer.

2. The method of claim 1, wherein a thickness of the silicon-rich nitride layer is less than about 40 Å.

3. The method of claim 1, wherein a gas flow ratio of NH₃ to SiH₂Cl₂ or SiH₄ is about 0.2-0.5.

4. The method of claim 1, wherein the silicon-rich nitride layer has a N/Si ratio of about 1.1-1.3.

5. The method of claim 1, wherein the bottom oxide layer comprises a silicon oxide layer.

6. The method of claim 1, wherein the top oxide layer comprises a silicon oxide layer or a high-k metal oxide layer.

7. The method of claim 1, wherein the step of forming the silicon-rich nitride layer comprises performing a LPCVD process, a PECVD process, an ECRCVD process or an ICPCVD process.

8. The method of claim 7 wherein a temperature of the LPCVD process is about 600-650° C.

9. The method of claim 1, further comprising forming two doped regions in the substrate beside the gate after the step of forming the gate.

10. A non-volatile memory, comprising:
a bottom oxide layer, a silicon-rich nitride layer and a top oxide layer sequentially disposed on a substrate, wherein a thickness of the silicon-rich nitride layer is less than about 40 Å; and
a gate, disposed on the top oxide layer.

11. The non-volatile memory of claim 10, wherein the silicon-rich silicon nitride layer has a N/Si ratio of about 1.1-1.3.

12. The non-volatile memory of claim 10, wherein the bottom oxide layer comprises a silicon oxide layer.

13. The non-volatile memory of claim 10, wherein the top oxide layer comprises a silicon oxide layer or a high-k metal oxide layer.

14. The non-volatile memory of claim 10, further comprising two doped regions disposed in the substrate beside the gate.
